(19) United States
(12) Patent Application Publication
(10) Pub. No.: US 2007/0040244 A1
(43) Pub. Date: Feb. 22, 2007

(54) Substrate for sensors

(75) Inventors: Yukou Saito, Kangawa (JP); Hirohiko Tsuzuki, Kanagawa (JP); Toshiaki Kubo, Saitama (JP)

Correspondence Address: SUGHRUE MION, PLLC, 2100 PENNSYLVANIA AVENUE, N.W., SUITE 800, WASHINGTON, DC, 20037, US

(73) Assignee: FUJI PHOTO FILM CO., LTD.

(21) Appl. No.: 11/504,078

(22) Filed: Aug. 15, 2006

(30) Foreign Application Priority Data
Aug. 16, 2005 (JP) 2005-235625

(51) Int. Cl. H01L 23/58

(52) U.S. Cl. 257/643

(57) ABSTRACT

It is an object of the present invention to provide a substrate for sensors and a container, wherein the adhesiveness of the substrate to a thin film is improved, a physiologically active substance can be immobilized without the peeling of the thin film from a plastic substrate, and non-specific adsorption during the analysis of interaction among biomolecules is small. The present invention provides a substrate for sensors, which has a thin film layer on a plastic substrate, wherein the plastic substrate has been treated with an organic primer before formation of the thin film.

### TECHNICAL FIELD

The present invention relates to a substrate for sensors and a container using a plastic substrate having a thin film on the surface thereof. The present invention particularly relates to a substrate for sensors which is used for a surface plasmon resonance analysis biosensor.

### BACKGROUND ART

Recently, a large number of measurements using intermolecular interactions such as immune responses are being carried out in clinical tests, etc. However, since conventional methods require complicated operations or labeling substances, several techniques are used that are capable of detecting the change in the binding amount of a test substance with high sensitivity without using such labeling substances. Examples of such a technique may include a surface plasmon resonance (SPR) measurement technique, a quartz crystal microbalance (QCM) measurement technique, and a measurement technique of using functional surfaces ranging from gold colloid particles to ultra-fine particles. The SPR measurement technique is a method of measuring changes in the refractive index near an organic functional film attached to the metal film of a chip by measuring a peak shift in the wavelength of reflected light, or changes in amounts of reflected light in a certain wavelength, so as to detect adsorption and desorption occurring near the surface. The QCM measurement technique is a technique of detecting adsorbed or desorbed mass at the ng level, using a change in frequency of a crystal due to adsorption or desorption of a substance on gold electrodes of a quartz crystal (device). In addition, the ultra-fine particle surface (nm level) of gold is functionalized, and physiologically active substances are immobilized thereon. Thus, a reaction to recognize specificity among physiologically active substances is carried out, thereby detecting a substance associated with a living organism from sedimentation of gold fine particles or sequences.

In all of the above-described techniques, the surface where a physiologically active substance is immobilized is important. Surface plasmon resonance (SPR), which is most commonly used in this technical field, will be described below as an example.

A commonly used measurement chip comprises a transparent substrate (e.g., glass), an evaporated metal film, and a thin film having thereon a functional group capable of immobilizing a physiologically active substance. The measurement chip immobilizes the physiologically active substance on the metal surface via the functional group. A specific binding reaction between the physiological active substance and a test substance is measured, so as to analyze an interaction between biomolecules.

As a thin film having a functional group capable of immobilizing a physiologically active substance, there has been reported a measurement chip where a physiologically active substance is immobilized by using a functional group binding to metal, a linker with a chain length of 10 or more atoms, and a compound having a functional group capable of binding to the physiologically active substance (Japanese Patent No. 2815120). Moreover, a measurement chip comprising a metal film and a plasma-polymerized film formed on the metal film has been reported (Japanese Patent Laid-Open No. 9-264843).

On the other hand, when a thin film is formed on a plastic substrate, and a physiologically active substance is then immobilized on the surface of the thin film, such a treatment has been problematic in that adhesive strength between the plastic substrate and the thin film becomes insufficient, in that the thin film is peeled from the substrate, and thus in that non-specific adsorption of biomolecules onto the substrate is likely to generate during the production of a sensor and the analysis of interaction among the biomolecules. In particular, the above treatment has been problematic in that if the thin film is allowed to come into contact with an aqueous solution or an organic solvent, it often causes trouble.

### DISCLOSURE OF THE INVENTION

It is an object of the present invention to solve the aforementioned problem. That is to say, it is an object of the present invention to provide a substrate for sensors and a container, wherein the adhesiveness of the substrate to a thin film is improved, a physiologically active substance can be immobilized without the peeling of the thin film from a plastic substrate, and non-specific adsorption during the analysis of interaction among biomolecules is small.

As a result of intensive studies directed towards achieving the aforementioned object, the present inventors have found that the aforementioned object can be achieved by subjecting a thin film surface, which has been formed after treating a plastic substrate surface with an organic primer, to a treatment for immobilizing a physiologically active substance, thereby completing the present invention.

The present invention provides a substrate for sensors, which has a thin film layer on a plastic substrate, wherein the plastic substrate has been treated with an organic primer before formation of the thin film.

Preferably, the treatment with an organic primer is carried out by coating the molded plastic substrate with a primer agent.

Preferably, the treatment with an organic primer is carried out by previously mixing a primer agent into a plastic material in an amount of 0.1% by weight to 10% by weight based on the weight of the plastic material, and then molding the mixture into the plastic substrate.

Preferably, the organic primer is a compound represented by the formula: R¹—X—R² wherein each of R¹ and R² independently represents H or CₙH₂ₙ₊₁ wherein n represents an integer between 1 and 30; and X represents —C(═O)O—, —O—, —C═O—, —N(R)— wherein R represents a hydrogen atom or a lower alkyl group, or —N(R²)N(R¹)— wherein each of R¹ and R² independently represents a hydrogen atom or a lower alkyl group.

Preferably, n is an integer between 10 and 20.

Preferably, the material of the thin film is a metal or a metal oxide.

Preferably, the material of the thin film consists of a free electron metal selected from the group consisting of gold, silver, copper, platinum, and aluminum.

Preferably, the substrate for sensors according to the present invention is a substrate for biosensors.

Preferably, the substrate for sensors according to the present invention is used in non-electrochemical detection, and is more preferably used in surface plasmon resonance analysis.

Preferably, a linker molecule having a functional group capable of immobilizing a physiologically active substance is bound to the surface of a vacuum formed film layer via a chemical bond.

Preferably, a polymer film having a functional group capable of immobilizing a physiologically active substance is formed on the surface of a vacuum formed film layer.

Preferably, the functional group capable of immobilizing a physiologically active substance is —OH, —SH, —COOH, —NR¹R² (wherein R¹ and R² each independently represents a hydrogen atom or lower alkyl group), —CHO, —NR³NR¹R² (wherein each of R¹, R², and R³ independently represents a hydrogen atom or lower alkyl group), —NCO, —NCS, an epoxy group, or a vinyl group.

Preferably, the plastic substrate is substantially transparent.

Preferably, the plastic material that constitutes the substrate is a material having a norbornene skeleton.

Preferably, in the substrate for sensors according to the present invention, a physiologically active substance is bound to the surface via a covalent bond.

In another aspect, the present invention provides a container having a thin film layer on a plastic substrate, wherein the plastic substrate has been treated with an organic primer before formation of the thin film.

### BEST MODE FOR CARRYING OUT THE INVENTION

The embodiments of the present invention will be described below.

The substrate of the present invention is a substrate having a vacuum formed film layer on a plastic substrate treated with an organic primer, which is characterized in that it is allowed to come into contact with a liquid after the vacuum forming of a film.

The term “organic primer” is used in the present invention to mean an organic substance for improving the adhesiveness of the surface of a plastic substrate to a vacuum formed thin film. An example of a resin organic primer is an epoxy/phenol resin, a polyamide resin, and a mixture of a resorcinol resin and a rubber latex. In addition, a low molecular weight compound can also be used as an organic primer. When the organic primer is such a low molecular weight compound, it is possible not only to apply it to a plastic substrate, but also to mix it with a plastic material before molding and then to mold the obtained mixture, thereby forming a primer layer on the surface of the substrate. A preferred low molecular weight organic primer agent can be represented by the formula R¹—X—R².

Herein, each of R¹ and R² independently represents H or CₙH₂ₙ₊₁ wherein n represents an integer between 1 and 30; and X represents —C(═O)O—, —O—, —C═O—, —N(R)— (wherein R represents a hydrogen atom or a lower alkyl group), or —N(R²)N(R¹)— (wherein each of R¹ and R² independently represents a hydrogen atom or a lower alkyl group).

The term “lower alkyl group” is generally used in the present specification to mean an alkyl group containing approximately 1 to 10 carbon atoms, preferably an alkyl group containing 1 to 8 carbon atoms, and more preferably an alkyl group containing 1 to 6 carbon atoms. Particularly preferably, each of R¹ and R² independently represents H or CₙH₂ₙ₊₁ wherein n represents an integer between 1 and 20. In the case of a carbon chain, it is preferably constituted with only a linear structure having no branches.

Since a carbon chain constituting an organic primer has a linear structure, even if stress is given between a plastic substrate and a thin film, exfoliation can be alleviated. Preferred examples of an organic primer material may include: higher fatty acid alcohols such as palmityl alcohol or stearyl alcohol; higher fatty acids such as stearic acid or 12-hydroxy stearic acid; and higher fatty acid esters such as n-butyl myristate.

As a primer treatment method, a coating method can be used. Such coating can be carried out according to common methods. Examples of such a coating method may include spin coating, air-knife coating, bar coating, blade coating, slide coating, curtain coating, spray method, evaporation method, casting method, and immersion method. As a preferred organic primer treatment of a substrate surface, a primer agent has previously been mixed into a plastic material in an amount between 0.1% by weight and 10% by weight based on the weight of the plastic material, and the mixture is then molded into a plastic substrate. In this case, if the amount of a primer agent is too small, the adhesive strength between the plastic substrate and a vacuum formed film layer is decreased. In contrast, if the amount of a primer agent is too large, it causes problems such as a decrease in the optical properties or strength of the plastic substrate.

Preferably, the plastic substrate is substantially transparent, because it can be non-electrochemically detected. A preferred plastic material is a material having low hygroscopicity, low water-absorbing properties, and high transparency. Specifically, a material having a norbornene skeleton is preferred.

Preferred examples of such a plastic substrate used herein may include materials that are transparent to laser light, such as polymethyl methacrylate, polyethylene terephthalate, polycarbonate, or a cycloolefin polymer. Such a substrate is preferably made from a material, which does not exhibit anisotropy to polarized light and is excellent in terms of processability. Such a material is particularly preferably a hydrocarbon polymer having a norbornene skeleton.

A thin film may be formed by common methods. Examples of such a common method may include sputtering method, evaporation method, ion-plating method, and plating method. A thin film material is selected from among a metal, a metal oxide, a semiconductor, and an organic substance. The thin film material is preferably a metal or a metal oxide. It is more preferably a free-electron metal selected from the group consisting of gold, silver, copper, platinum, and aluminum. The metal is not particularly limited, as long as surface plasmon resonance is generated when the metal is used for a surface plasmon resonance biosensor. Examples of a preferred metal may include free-electron metals such as gold, silver, copper, aluminum or platinum. Of these, gold is particularly preferable. These metals can be used singly or in combination. Moreover, considering adherability to the above substrate, an interstitial layer consisting of chrome or the like may be provided between the substrate and a metal layer.

The film thickness of a metal film is not limited. When the metal film is used for a surface plasmon resonance biosensor, the thickness is preferably between 0.1 nm and 500 nm, and particularly preferably between 1 nm and 200 nm. If the thickness exceeds 500 nm, the surface plasmon phenomenon of a medium cannot be sufficiently detected. Moreover, when an interstitial layer consisting of chrome or the like is provided, the thickness of the interstitial layer is preferably between 0.1 nm and 10 nm.

After formation of a thin film, the surface of a substrate is chemically modified, so that it can immobilize a physiologically active substance thereon. Thereby, interaction among biomolecules is converted to signals such as electric signals, and as a result, it becomes possible to measure or detect a substance as a target. Thus, a chemical modification is useful. As the chemical modification, a functional group capable of forming a covalent bond with a physiologically active substance can be introduced into the surface of a substrate in an aqueous solution or in an organic solvent according to common methods.

Preferred functional group capable of forming a covalent bond with a physiologically active substance includes —OH, —SH, —COOH, —NR¹R² (wherein each of R¹ and R² independently represents a hydrogen atom or lower alkyl group), —CHO, —NR³NR¹R² (wherein each of R¹, R²and R³ independently represents a hydrogen atom or lower alkyl group), —NCO, —NCS, an epoxy group, or a vinyl group. The number of carbon atoms contained in the lower alkyl group is not particularly limited herein. However, it is generally about C1 to C10, and preferably C1 to C6.

Examples of a linker molecule preferably used in the present invention may include: proteins such as albumin or casein; sugar derivatives such as agar, sodium alginate, or a starch derivative; cellulose compounds such as carboxymethyl cellulose or hydroxymethyl cellulose; polysaccharides such as chitin or chitosan; and synthetic hydrophilic polymers such as polyvinyl alcohol, poly-N-vinylpyrrolidone, polyacrylamide, or polyacrylic acid. A hydrophilic polymer compound can be applied to a substrate according to common coating methods. Examples of such a common coating method may include spin coating, air-knife coating, bar coating, blade coating, slide coating, curtain coating, spray method, evaporation method, casting method, and immersion method.

A polymer film material preferably used in the present invention may include polystyrene, polyethylene, polypropylene, polyethylene terephthalate, polyvinyl chloride, polymethyl methacrylate, polyester, and nylon. These polymer materials can be subjected to a surface treatment, such as a chemical treatment using chemicals, coupling agents, surfactants, surface evaporation, etc., or a physical treatment using heat, ultraviolet ray, radioactive ray, plasma, ions, etc.

In order to introduce these functional groups into the surface, a method is applied that involves applying a hydrophobic polymer containing a precursor of such a functional group on a metal surface or metal film, and then generating the functional group from the precursor located on the outermost surface by chemical treatment. For example, polymethyl methacrylate, a hydrophobic polymer containing —COOCH₃ group, is applied on a metal film, and then the surface comes into contact with an NaOH aqueous solution (1N) at 40° C. for 16 hours, so that a —COOH group is generated on the outermost surface. In addition, when a polystyrene coating layer is subjected to a UV/ozone treatment for example, a —COOH group and a —OH group are generated on the outermost surface thereof.

The conventional biosensor is comprised of a receptor site for recognizing a chemical substance as a detection target and a transducer site for converting a physical change or chemical change generated at the site into an electric signal. In a living body, there exist substances having an affinity with each other, such as enzyme/substrate, enzyme/coenzyme, antigen/antibody, or hormone/receptor. The biosensor operates on the principle that a substance having an affinity with another substance, as described above, is immobilized on a substrate to be used as a molecule-recognizing substance, so that the corresponding substance can be selectively measured.

A physiologically active substance is covalently bound to the above-obtained substrate for sensor via the above functional group, so that the physiologically active substance can be immobilized on the metal surface or metal film.

A physiologically active substance immobilized on the substrate for sensor of the present invention is not particularly limited, as long as it interacts with a measurement target. Examples of such a substance may include an immune protein, an enzyme, a microorganism, nucleic acid, a low molecular weight organic compound, a nonimmune protein, an immunoglobulin-binding protein, a sugar-binding protein, a sugar chain recognizing sugar, fatty acid or fatty acid ester, and polypeptide or oligopeptide having a ligand-binding ability.

Examples of an immune protein may include an antibody whose antigen is a measurement target, and a hapten. Examples of such an antibody may include various immunoglobulins such as IgG, IgM, IgA, IgE or IgD. More specifically, when a measurement target is human serum albumin, an anti-human serum albumin antibody can be used as an antibody. When an antigen is an agricultural chemical, pesticide, methicillin-resistant Staphylococcus aureus, antibiotic, narcotic drug, cocaine, heroin, crack or the like, there can be used, for example, an anti-atrazine antibody, anti-kanamycin antibody, anti-metamphetamine antibody, or antibodies against O antigens 26, 86, 55, 111 and 157 among enteropathogenic Escherichia coli.

An enzyme used as a physiologically active substance herein is not particularly limited, as long as it exhibits an activity to a measurement target or substance metabolized from the measurement target. Various enzymes such as oxidoreductase, hydrolase, isomerase, lyase or synthetase can be used. More specifically, when a measurement target is glucose, glucose oxidase is used, and when a measurement target is cholesterol, cholesterol oxidase is used. Moreover, when a measurement target is an agricultural chemical, pesticide, methicillin-resistant Staphylococcus aureus, antibiotic, narcotic drug, cocaine, heroin, crack or the like, enzymes such as acetylcholine esterase, catecholamine esterase, noradrenalin esterase or dopamine esterase, which show a specific reaction with a substance metabolized from the above measurement target, can be used.

A microorganism used as a physiologically active substance herein is not particularly limited, and various microorganisms such as Escherichia coli can be used.

As nucleic acid, those complementarily hybridizing with nucleic acid as a measurement target can be used. Either DNA (including cDNA) or RNA can be used as nucleic acid. The type of DNA is not particularly limited, and any of native DNA, recombinant DNA produced by gene recombination and chemically synthesized DNA may be used.

As a low molecular weight organic compound, any given compound that can be synthesized by a common method of synthesizing an organic compound can be used.

A nonimmune protein used herein is not particularly limited, and examples of such a nonimmune protein may include avidin (streptoavidin), biotin, and a receptor.

Examples of an immunoglobulin-binding protein used herein may include protein A, protein G, and a rheumatoid factor (RF).

As a sugar-binding protein, for example, lectin is used.

Examples of fatty acid or fatty acid ester may include stearic acid, arachidic acid, behenic acid, ethyl stearate, ethyl arachidate, and ethyl behenate.

When the physiologically active substance is a protein such as antibody or enzyme, or DNA, the immobilization thereof can be carried out by covalently binding it to the functional group on the metal surface using an amino group, a thiol group or the like of the physiologically active substance.

A biosensor to which a physiologically active substance is immobilized as described above can be used to detect and/or measure a substance which interacts with the physiologically active substance.

Thus, the present invention provides a method for detecting or measuring a substance interacting with a physiologically active substance which is immobilized on the biosensor of the present invention, wherein the biosensor of the present invention to which the physiologically active substance is immobilized is used, and a test substance is allowed to come into contact with said biosensor.

As the test substance, a sample containing a substance interacting with the aforementioned physiologically active substance, or the like, can be used.

A preferred use of the substrate for sensors according to the present invention is a substrate for sensors and a container, which are allowed to come into contact with an aqueous solution or an organic solvent. A liquid to be allowed to come into contact with the substrate preferably has pH of 8 or greater because of the surface modification of a vacuum formed film layer and immobilization of a physiologically active substance. For the purpose of realizing dehydration and deacidification, such a liquid to be allowed to come into contact with the substrate more preferably has pH of 10 or greater.

The form of a container used in the present invention is not particularly limited, as long as it is able to contain a liquid (for example, a liquid that contains a physiologically active substance such as a protein or an agent such as a low molecular weight compound). Examples of the container may include a tube and a plate (e.g. 96-well plate, etc.).

In the present invention, the interaction of a physiologically active substance immobilized on the biosensor surface with a test substance is preferably detected and/or measured by a non-electrochemical method. Examples of such a non-electrochemical method may include the surface plasmon resonance (SPR) measurement technique, the quartz crystal microbalance (QCM) measurement technique, and a measurement technique using a functionalized surface ranging from colloidal gold particles to ultra-fine particles.

In a preferred embodiment of the present invention, the biosensor of the present invention can be used as a biosensor for surface plasmon resonance which is characterized in that it comprises a metal film placed on a transparent substrate.

A biosensor for surface plasmon resonance is a biosensor used for a surface plasmon resonance biosensor, meaning a member comprising a portion for transmitting and reflecting light emitted from the sensor and a portion for immobilizing a physiologically active substance. It may be fixed to the main body of the sensor or may be detachable.

The surface plasmon resonance phenomenon occurs due to the fact that the intensity of monochromatic light reflected from the border between an optically transparent substance such as glass and a metal thin film layer depends on the refractive index of a sample located on the outgoing side of the metal. Accordingly, the sample can be analyzed by measuring the intensity of reflected monochromatic light.

A device using a system known as the Kretschmann configuration is an example of a surface plasmon measurement device for analyzing the properties of a substance to be measured using a phenomenon whereby a surface plasmon is excited with a lightwave (for example, Japanese Patent Laid-Open No. 6-167443). The surface plasmon measurement device using the above system basically comprises a dielectric block formed in a prism state, a metal film that is formed on a face of the dielectric block and comes into contact with a measured substance such as a sample solution, a light source for generating a light beam, an optical system for allowing the above light beam to enter the dielectric block at various angles so that total reflection conditions can be obtained at the interface between the dielectric block and the metal film, and a light-detecting means for detecting the state of surface plasmon resonance, that is, the state of attenuated total reflection, by measuring the intensity of the light beam totally reflected at the above interface.

In order to achieve various incident angles as described above, a relatively thin light beam may be caused to enter the above interface while changing an incident angle. Otherwise, a relatively thick light beam may be caused to enter the above interface in a state of convergent light or divergent light, so that the light beam contains components that have entered therein at various angles. In the former case, the light beam whose reflection angle changes depending on the change of the incident angle of the entered light beam can be detected with a small photodetector moving in synchronization with the change of the above reflection angle, or it can also be detected with an area sensor extending along the direction in which the reflection angle is changed. In the latter case, the light beam can be detected with an area sensor extending to a direction capable of receiving all the light beams reflected at various reflection angles.

With regard to a surface plasmon measurement device with the above structure, if a light beam is allowed to enter the metal film at a specific incident angle greater than or equal to a total reflection angle, then an evanescent wave having an electric distribution appears in a measured substance that is in contact with the metal film, and a surface plasmon is excited by this evanescent wave at the interface between the metal film and the measured substance. When the wave vector of the evanescent light is the same as that of a surface plasmon and thus their wave numbers match, they are in a resonance state, and light energy transfers to the surface plasmon. Accordingly, the intensity of totally reflected light is sharply decreased at the interface between the dielectric block and the metal film. This decrease in light intensity is generally detected as a dark line by the above light-detecting means. The above resonance takes place only when the incident beam is p-polarized light. Accordingly, it is necessary to set the light beam in advance such that it enters as p-polarized light.

If the wave number of a surface plasmon is determined from an incident angle causing the attenuated total reflection (ATR), that is, an attenuated total reflection angle (θSP), the dielectric constant of a measured substance can be determined. As described in Japanese Patent Laid-Open No. 11-326194, a light-detecting means in the form of an array is considered to be used for the above type of surface plasmon measurement device in order to measure the attenuated total reflection angle (θSP) with high precision and in a large dynamic range. This light-detecting means comprises multiple photo acceptance units that are arranged in a certain direction, that is, a direction in which different photo acceptance units receive the components of light beams that are totally reflected at various reflection angles at the above interface.

In the above case, there is established a differentiating means for differentiating a photodetection signal outputted from each photo acceptance unit in the above array-form light-detecting means with regard to the direction in which the photo acceptance unit is arranged. An attenuated total reflection angle (θSP) is then specified based on the derivative value outputted from the differentiating means, so that properties associated with the refractive index of a measured substance are determined in many cases.

In addition, a leaking mode measurement device described in “Bunko Kenkyu (Spectral Studies)” Vol. 47, No. 1 (1998), pp. 21 to 23 and 26 to 27 has also been known as an example of measurement devices similar to the above-described device using attenuated total reflection (ATR). This leaking mode measurement device basically comprises a dielectric block formed in a prism state, a clad layer that is formed on a face of the dielectric block, a light wave guide layer that is formed on the clad layer and comes into contact with a sample solution, a light source for generating a light beam, an optical system for allowing the above light beam to enter the dielectric block at various angles so that total reflection conditions can be obtained at the interface between the dielectric block and the clad layer, and a light-detecting means for detecting the excitation state of waveguide mode, that is, the state of attenuated total reflection, by measuring the intensity of the light beam totally reflected at the above interface.

In the leaking mode measurement device with the above structure, if a light beam is caused to enter the clad layer via the dielectric block at an incident angle greater than or equal to a total reflection angle, only light having a specific wave number that has entered at a specific incident angle is transmitted in a waveguide mode into the light wave guide layer, after the light beam has penetrated the clad layer. Thus, when the waveguide mode is excited, almost all forms of incident light are taken into the light wave guide layer, and thereby the state of attenuated total reflection occurs, in which the intensity of the totally reflected light is sharply decreased at the above interface. Since the wave number of a waveguide light depends on the refractive index of a measured substance placed on the light wave guide layer, the refractive index of the measurement substance or the properties of the measured substance associated therewith can be analyzed by determining the above specific incident angle causing the attenuated total reflection.

In this leaking mode measurement device also, the above-described array-form light-detecting means can be used to detect the position of a dark line generated in a reflected light due to attenuated total reflection. In addition, the above-described differentiating means can also be applied in combination with the above means.

The above-described surface plasmon measurement device or leaking mode measurement device may be used in random screening to discover a specific substance binding to a desired sensing substance in the field of research for development of new drugs or the like. In this case, a sensing substance is immobilized as the above-described measured substance on the above thin film layer (which is a metal film in the case of a surface plasmon measurement device, and is a clad layer and a light guide wave layer in the case of a leaking mode measurement device), and a sample solution obtained by dissolving various types of test substance in a solvent is added to the sensing substance. Thereafter, the above-described attenuated total reflection angle (θSP) is measured periodically when a certain period of time has elapsed.

If the test substance contained in the sample solution is bound to the sensing substance, the refractive index of the sensing substance is changed by this binding over time. Accordingly, the above attenuated total reflection angle (θSP) is measured periodically after the elapse of a certain time, and it is determined whether or not a change has occurred in the above attenuated total reflection angle (θSP), so that a binding state between the test substance and the sensing substance is measured. Based on the results, it can be determined whether or not the test substance is a specific substance binding to the sensing substance. Examples of such a combination between a specific substance and a sensing substance may include an antigen and an antibody, and an antibody and an antibody. More specifically, a rabbit anti-human IgG antibody is immobilized as a sensing substance on the surface of a thin film layer, and a human IgG antibody is used as a specific substance.

It is to be noted that in order to measure a binding state between a test substance and a sensing substance, it is not always necessary to detect the angle itself of an attenuated total reflection angle (θSP). For example, a sample solution may be added to a sensing substance, and the amount of an attenuated total reflection angle (θSP) changed thereby may be measured, so that the binding state can be measured based on the magnitude by which the angle has changed. When the above-described array-form light-detecting means and differentiating means are applied to a measurement device using attenuated total reflection, the amount by which a derivative value has changed reflects the amount by which the attenuated total reflection angle (θSP) has changed. Accordingly, based on the amount by which the derivative value has changed, a binding state between a sensing substance and a test substance can be measured (Japanese Patent Application No. 2000-398309 filed by the present applicant). In a measuring method and a measurement device using such attenuated total reflection, a sample solution consisting of a solvent and a test substance is added dropwise to a cup- or petri dish-shaped measurement chip wherein a sensing substance is immobilized on a thin film layer previously formed at the bottom, and then, the above-described amount by which an attenuated total reflection angle (θSP) has changed is measured.

Moreover, Japanese Patent Laid-Open No. 2001-330560 describes a measurement device using attenuated total reflection, which involves successively measuring multiple measurement chips mounted on a turntable or the like, so as to measure many samples in a short time.

When the biosensor of the present invention is used in surface plasmon resonance analysis, it can be applied as a part of various surface plasmon measurement devices described above.

The present invention will be further specifically described in the following examples. However, the examples are not intended to limit the scope of the present invention.

### EXAMPLES

### Example 1

### Substrate (1) of the Present Invention

A Zeonex (manufactured by Zeon Corp.) pellet was melted at 240° C. Thereafter, using an injection molding device, the obtained melt was molded into a substrate having a size of 8 mm long×120 mm wide×1.5 mm height. This substrate was placed in an aluminum container having a hermetically closed structure of 30 mm long×130 mm wide×10 mm deep. This aluminum container was fixed on the inner cup of a spin-coater (MODEL SC408; manufactured by Nanometric Technology Inc.) equipped with a hermetically closed inner cup, such that the gold surface substrate was positioned at 135 mm from the center and such that the tangential direction of a circular arc became a long axis. 100 μl of an ethanol solution containing 0.2% 12-hydroxy stearic acid was added dropwise to the substrate, using a micropipette, so that the entire surface of the gold surface substrate was coated with coating solution A. The aluminum container was hermetically sealed, and it was then left at rest for 30 seconds. Thereafter, it was rotated at 200 rpm for 60 seconds. Using a parallel-plate-type 6-inch sputtering apparatus (SH-550; manufactured by Ulvac Inc.), a gold film was formed on the substrate by a sputtering technique, resulting in a gold thickness of 50 nm, so as to produce the substrate (1) of the present invention.

### Example 2

### Substrate (2) of the Present Invention

The substrate (2) of the present invention was produced by the same method as that described in Example 1, with the exception that palmityl alcohol was used instead of 12-hydroxy stearic acid.

### Example 3

### Substrate (3) of the Present Invention

12-hydroxy stearic acid was added to the Zeonex (manufactured by Zeon Corp.) pellet, in an additive amount of 1% by weight based on the total weight. Thereafter, the mixture was melted and mixed at 240° C. Thereafter, using an injection molding device, the obtained melt was molded into a substrate having a size of 8 mm long×120 mm wide×1.5 mm height. Using a parallel-plate-type 6-inch sputtering apparatus (SH-550; manufactured by Ulvac Inc.), a gold film was formed on the substrate by a sputtering technique, resulting in a gold thickness of 50 nm, so as to produce the substrate (3) of the present invention.

### Comparative Example

### Substrate of Comparative Example

The substrate of the comparative example was produced by the same method as that described in Example 3 with the exception that 12-hydroxy stearic acid was not added.

### Test Example 1

### Evaluation of Gold Film Adhesiveness

With regard to the substrates (1), (2) and (3) of the present invention and the substrate of the comparative example, 5.0 mM 11-hydroxy-1-undecanethiol solution in ethanol/water (80/20) was added to each substrate in such a way that the solution was allowed come into contact with the gold film of the substrate, so as to carry out a surface treatment at 25° C. for 18 hours. Thereafter, the resultant substrate was washed with ethanol 5 times, then with a mixed solvent of ethanol/water once, and then with water 5 times.

Subsequently, the surface coated with 11-hydroxy-1-undecanethiol was allowed to come into contact with 10% by weight of an epichlorohydrin solution (solvent: a mixed solution of 0.4 M sodium hydroxide and diethylene glycol dimethyl ether at a mixing ratio of 1:1), and the reaction was carried out in a shaking incubator at 25° C. for 4 hours. Thereafter, the surface was washed with ethanol 2 times, and then with water 5 times.

Subsequently, 4.5 ml of 1 M sodium hydroxide was added to 40.5 ml of an aqueous solution that contained 25% by weight of dextran (T500, Pharmacia), and the obtained solution was then allowed to come into contact with the epichlorohydrin-treated surface. Thereafter, it was incubated in a shaking incubator at 25° C. for 20 hours. Thereafter, the surface was washed with water at 50° C. 10 times. Subsequently, a mixture obtained by dissolving 3.5 g of bromoacetic acid in 27 g of 2 M sodium hydroxide solution was allowed to come into contact with the aforementioned dextran-treated surface, and it was then incubated in a shaking incubator at 28° C. for 16 hours. Thereafter, the surface was washed with water, and the aforementioned procedure was then repeated once again. The thus produced substrate is called a dextran-immobilized substrate.

The gold film surface of the produced dextran substrate was observed under an optical microscope at a magnification of 200 times. In the case of substrates (1), (2), and (3) of the examples, exfoliation of the gold film from the Zeonex substrate was not observed, and thus it was good in terms of adhesiveness. On the other hand, in the case of the substrate of the comparative example, exfoliation of 10 gold film portions each having a diameter of approximately 10 μm was observed per area of 1 mm², and thus it was poor in terms of adhesiveness.

### Test Example 2

### Evaluation of Non-Specific Adsorption Preventing Performance

Since non-specific adsorption of proteins on the biosensor surface causes noise, such non-specific adsorption preferably occurs at an extremely small degree. Using the dextran-immobilized substrate produced in Test example 1, the non-specific adsorption property of IL8 was measured.

The dextran-immobilized substrate produced in Test example 1 was installed in the device shown in FIG. 22 of Japanese Patent Application Laid-Open No. 2001-330560 (hereinafter referred to as the surface plasmon resonance device of the present invention). An HBS-N buffer (manufactured by Biacore) was added to the substrate, and it was then left at rest for 20 minutes. Thereafter, an IL8 solution (1 mg/ml HBS-N buffer) was added to the substrate, and it was then left at rest for 10 minutes. It is to be noted that the HBS-N buffer consists of 0.01 mol/l HEPES (N-2-hydroxyethylpiperazine-N′-2-ethanesulfonic acid) (pH 7.4) and 0.15 mol/l NaCl. Thereafter, the substrate was washed with the HBS-N buffer, and the amount of resonance signal (RU value) changed after 3 minutes was defined as the non-specific absorption amount of IL8. The measurement results are shown in Table 1. From the results shown in Table 1, it could be confirmed by surface plasmon resonance that a biosensor wherein the substrate of the present invention was used, had an extremely small degree of non-specific adsorption of proteins.

TABLE 1

| | Non-specific | |
|---|---|---|
| Sample | adsorption of IL8 | |
| Example 1 | 15 | RU |
| Example 2 | 30 | RU |
| Example 3 | 10 | RU |
| Comparative example | 100 | RU |

Thus, it was demonstrated that the present invention provides a substrate, which prevents exfoliation of a thin film from a plastic substrate during the production of the substrate and has only a small degree of non-specific adsorption during the analysis of interaction among biomolecules.

### EFFECT OF THE INVENTION

According to the present invention, it became possible to provide a substrate wherein the adhesiveness of the substrate to a gold film is improved, a physiologically active substance can be immobilized without the peeling of the thin film from a plastic substrate, and non-specific adsorption during the analysis of interaction among biomolecules is small.

1. A substrate for sensors, which has a thin film layer on a plastic substrate, wherein the plastic substrate has been treated with an organic primer before formation of the thin film.

2. The substrate for sensors according to claim 1, wherein the treatment with an organic primer is carried out by coating the molded plastic substrate with a primer agent.

3. The substrate for sensors according to claim 1, wherein the treatment with an organic primer is carried out by previously mixing a primer agent into a plastic material in an amount of 0.1% by weight to 10% by weight based on the weight of the plastic material, and then molding the mixture into the plastic substrate.

4. The substrate for sensors according to claim 1, wherein the organic primer is a compound represented by the formula: R¹—X—R² wherein each of R¹ and R² independently represents H or CₙH₂ₙ₊₁ wherein n represents an integer between 1 and 30; and X represents —C(═O)O—, —O—, —C═O—, —N(R)— wherein R represents a hydrogen atom or a lower alkyl group, or —N(R²)N(R¹)— wherein each of R¹ and R² independently represents a hydrogen atom or a lower alkyl group.

5. The substrate for sensors according to claim 4, wherein n is an integer between 10 and 20.

6. The substrate for sensors according to claim 1, wherein the material of the thin film is a metal or a metal oxide.

7. The substrate for sensors according to claim 6, wherein the material of the thin film consists of a free electron metal selected from the group consisting of gold, silver, copper, platinum, and aluminum.

8. The substrate for sensors according to claim 1, which is a substrate for biosensors.

9. The substrate for sensors according to claim 1, which is used in non-electrochemical detection.

10. The substrate for sensors according to claim 1, which is used in surface plasmon resonance analysis.

11. The substrate for sensors according to claim 1, wherein a linker molecule having a functional group capable of immobilizing a physiologically active substance is bound to the surface of a vacuum formed film layer via a chemical bond.

12. The substrate for sensors according to claim 1, wherein a polymer film having a functional group capable of immobilizing a physiologically active substance is formed on the surface of a vacuum formed film layer.

13. The substrate for sensors according to claim 11, wherein the functional group capable of immobilizing a physiologically active substance is —OH, —SH, —COOH, —NR¹R² (wherein R¹ and R² each independently represents a hydrogen atom or lower alkyl group), —CHO, —NR³NR¹R² (wherein each of R¹, R², and R³ independently represents a hydrogen atom or lower alkyl group), —NCO, —NCS, an epoxy group, or a vinyl group.

14. The substrate for sensors according to claim 12, wherein the functional group capable of immobilizing a physiologically active substance is —OH, —SH, —COOH, —NR¹R² (wherein R¹ and R² each independently represents a hydrogen atom or lower alkyl group), —CHO, —NR³NR¹R² (wherein each of R¹, R², and R³ independently represents a hydrogen atom or lower alkyl group), —NCO, —NCS, an epoxy group, or a vinyl group.

15. The substrate for sensors according to claim 1, wherein the plastic substrate is substantially transparent.

16. The substrate for sensors according to claim 1, wherein the plastic material that constitutes the substrate is a material having a norbornene skeleton.

17. The substrate for sensors according to claim 1, wherein a physiologically active substance is bound to the surface via a covalent bond.

18. A container having a thin film layer on a plastic substrate, wherein the plastic substrate has been treated with an organic primer before formation of the thin film.
